(19) United States
(12) Patent Application Publication
(10) Pub. No.: US 2014/0002972 A1
(43) Pub. Date: Jan. 2, 2014

(54) HOUSING ASSEMBLY AND ELECTRONIC DEVICE USING THE SAME

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventors: JU-PING DUAN, Shenzhen (CN); MING-FU LUO, Shenzhen (CN); FA-GUANG SHI, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/848,838

(22) Filed: Mar. 22, 2013

(30) Foreign Application Priority Data
Jul. 2, 2012 (CN) 2012102245076

(51) Int. Cl. H05K 5/02

(52) U.S. Cl. CPC H05K 5/0247
USPC 361/679.01; 174/549

(57) ABSTRACT

A housing assembly includes a housing and a bumper insert. A jack socket hole is defined in the housing. The bumper insert is made of plastic material, and inserted in the jack socket hole to protect the jack socket hole. A connecting hole is defined through a mounting portion of the bumper insert. The disclosure also provides an electronic device using the housing assembly.

### BACKGROUND

1. Technical Field

The present disclosure generally relates to housing assemblies, and particularly to a housing assembly with a metal housing for an electronic device.

2. Description of the Related Art

Metal housings are applied in electronic devices for improving appearance and structural strength. Jack sockets are holes or receptacles defined in the housing for facilitating or providing electrical connections from other electronic devices or accessories, such as a power jack socket for connecting to a power plug, and an earphone jack socket for connecting with an earphone plug. However, plugs are made of electrically-conductive metal. Such metal plugs are easily damaged when the plugs are inserted into the jack sockets because of the friction exerted between the plugs and the inner walls of the holes. In addition, the inner walls and edges of the holes become scratched to negatively affect the appearance of the metal housing for electronic devices.

Therefore, there is room for improvement within the art.

### BRIEF DESCRIPTION OF THE DRAWING

The components in the drawings are not necessarily drawn to scale, the emphasis instead placed upon clearly illustrating the principles of the present disclosure. Moreover, in the drawings, like reference numerals designate corresponding parts throughout the several views.

FIG. 1 shows an isometric view of an electronic device having a housing assembly in according with a first embodiment of the present disclosure.

FIG. 2 is an isometric view of the housing assembly of FIG. 1.

FIG. 3 shows an exploded and isometric view of housing assembly of FIG. 2.

FIG. 4 is similar to FIG. 3, but viewed from another aspect.

FIG. 5 shows a cross-section of the housing assembly of FIG. 2, taken along a line labeled V-V.

FIG. 6 is a partial, exploded, isometric view of an electronic device in accordance with a second embodiment of the present disclosure.

### DETAILED DESCRIPTION

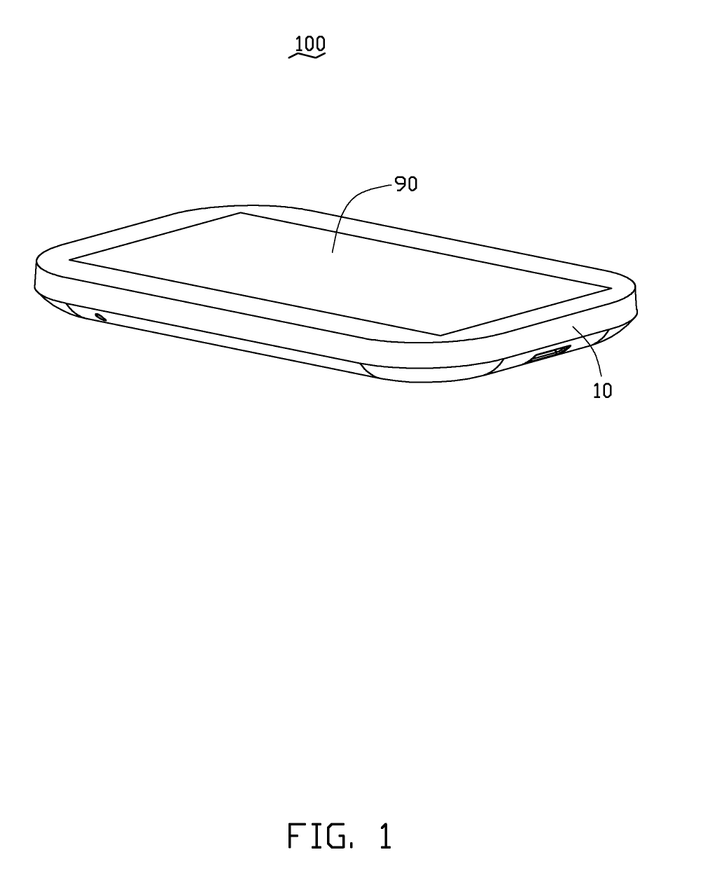

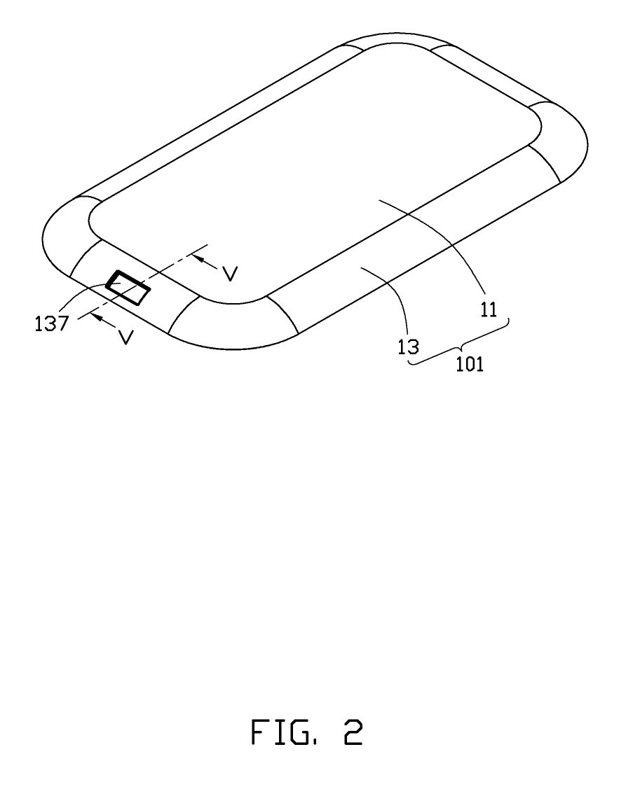

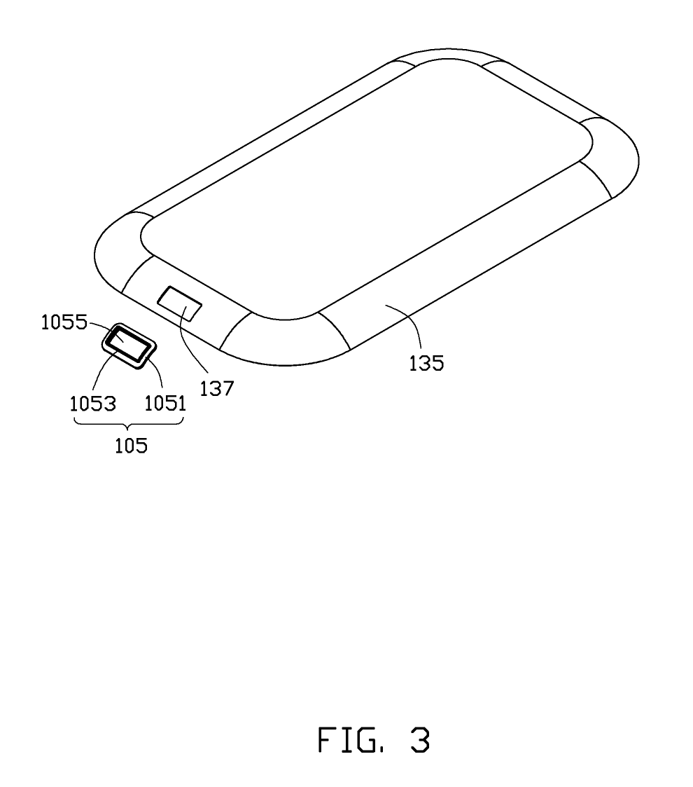

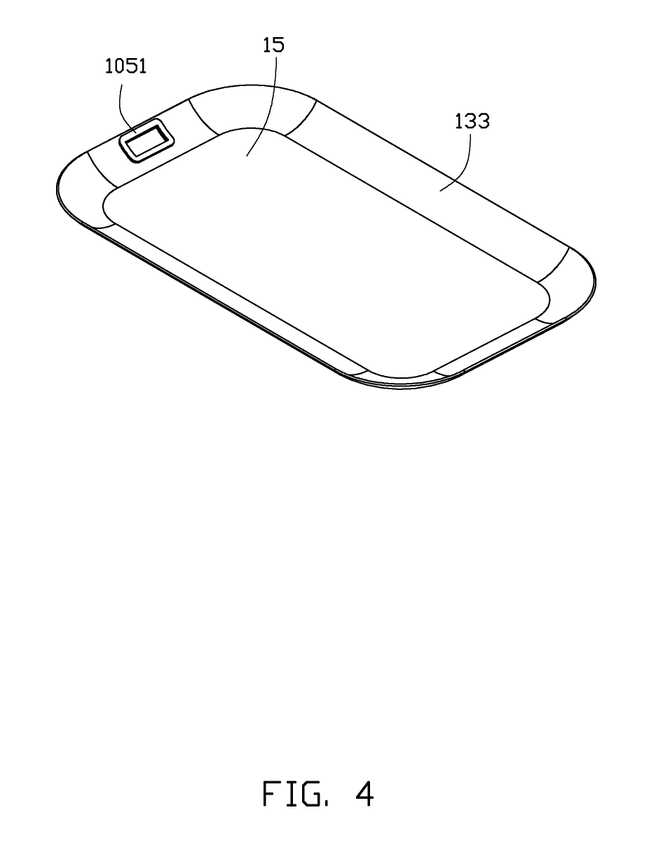

Referring to FIGS. 1 through 4, an electronic device 100 of a first embodiment is shown. The electronic device 100 includes a housing assembly 10, and a functional module 90 positioned in the housing assembly 10. The housing assembly 10 includes a housing 101 and a bumper insert 105 positioned in the housing 101. The functional module 90 is positioned in the housing 101. The functional module 90 includes a plurality of functional components, such as a battery, a camera, a main board, and a display panel. For the sake of simplicity and brevity, the functional module 90 is not fully described herein.

The housing 101 includes a bottom wall 11 and a peripheral wall 13 extending in a curved fashion or shape from the edges of the bottom wall 11. The bottom wall 11 and the peripheral wall 13 cooperatively form a receiving space 15 for receiving the functional module 90. The peripheral wall 13 includes an inner surface 133 and an outer surface 135 opposite to the inner surface 133. The inner surface 133 faces the receiving space 15. A jack socket hole 137 (a hole configured for jack socket) is defined and configured through the peripheral wall 13. In the illustrated embodiment, the jack socket hole 137 is a substantially rectangular hole formed in the peripheral wall 13 for connecting to a power plug (not shown). The functional module 90 is connected to an edge of the peripheral wall 13 and is received in the receiving space 15.

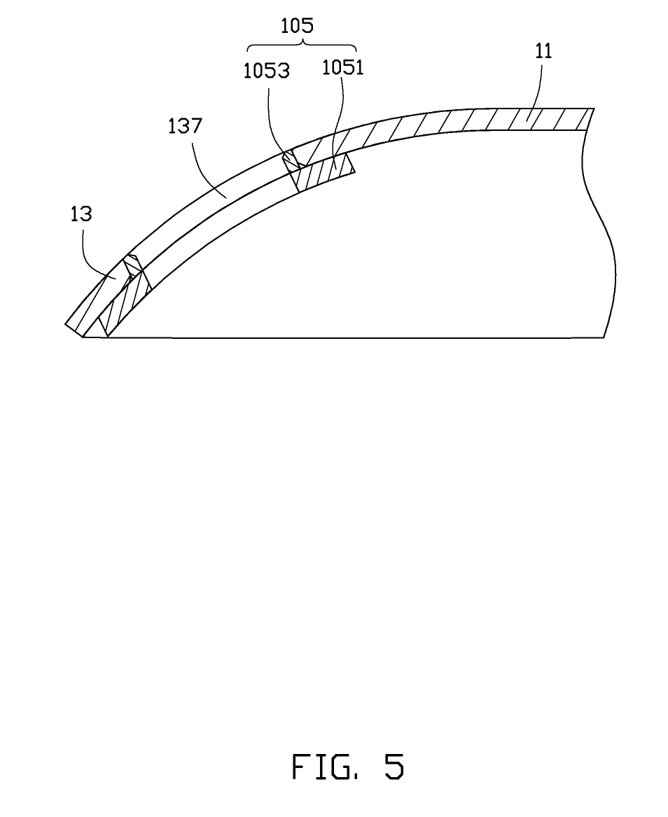

Also referring to FIG. 5, the bumper insert 105 is a substantially hollowed rectangular member corresponding to the jack socket hole 137. The bumper insert 105 is inserted in the jack socket hole 137, and an outer wall of the insertion portion 1053 conforms in size and shape to an inner wall of the jack socket hole 137 and the inner surface 133 of the peripheral wall 13. The bumper insert 105 is made of plastic material, such as rubber, polystyrene, or polyurethane. In the first embodiment, the bumper insert 105 is a singular, one-piece, and seamless (integral) body made of plastic material. The bumper insert 105 includes a mounting portion 1051 and an insertion portion 1053 protruding from the mounting portion 1051. The mounting portion 1051 conforms to and is fixed to the inner surface 133 around the jack socket hole 137 by adhesive. A connecting hole 1055 is defined through the mounting portion 1051 and the insertion portion 1053. The connecting hole 1055 is substantially rectangular. A shape and a size of the connecting hole 1055 matches the outline of a plug inserted into the connecting hole 1055. The insertion portion 1053 is inserted into the jack socket hole 137 and the outer wall surface of the insertion portion 1053 conforms to an inner surface of the jack socket hole 137. An end surface of the insertion portion 1053 away from the receiving space 15 is coplanar with the edges of the jack socket hole 137. In an alternative embodiment, the end surface of the insertion portion 1053 away from the receiving space 15 can be designed to protrude from the jack socket hole 137.

In use, the power plug of an external electronic device is inserted into the connecting hole 1055 and becomes electrically connected to the functional module 90.

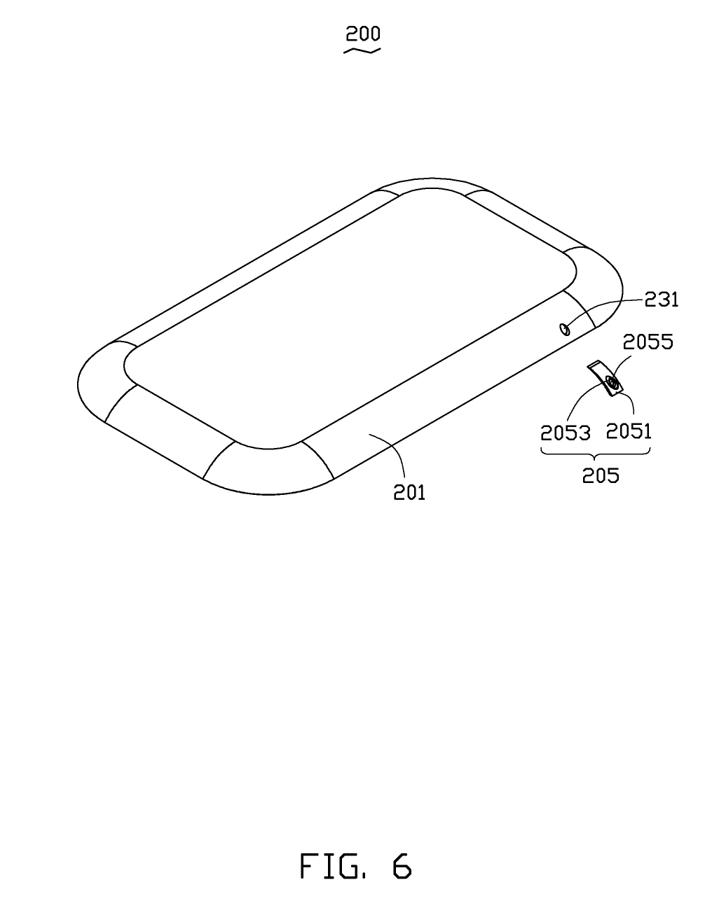

Referring to FIG. 6, an electronic device 200 of a second embodiment is shown. The electronic device 200 is similar to the electronic device 100, however, the difference is that a jack socket hole 231 of a housing 201 of the electronic device 200 is substantially circular in shape. A bumper insert 205 includes a substantially rectangular mounting portion 2051 and a substantially columnar insertion portion 2053. In the illustrated embodiment, the jack socket hole 231 is used for connecting to a earphone plug (not shown).

In other embodiments, the mounting portions 1051, 2051 can be omitted. Shapes of the jack socket holes 137, 231 can be of other shapes, and the shapes of the insertion portions 1053, 2053 can be made to correspond to those of the jack socket holes 137, 231. The number of the bumper inserts 105, 205 correspond to the number of the jack socket holes 137. The bumper inserts 105, 205 can be directly formed in the peripheral wall 13 by insert molding.

The bumper inserts 105, 205 are positioned in the jack socket holes 137, 231 of the electronic devices 100, 200. The bumper inserts 105, 205 protect the plugs from friction when the plugs are being inserted into the jack socket holes 137, 231. The cosmetic appearance of the housing 101 is maintained or preserved despite repeated usages of plugs inserting to and from the jacks 137, 231 because the edges of the jack socket holes 137, 231 do not directly touch, rub against, or contact with the plugs. The bumper inserts 105, 205 are made of plastic material, and directly formed by insert molding. There is no need for the jack sockets to be chamfered and milled or otherwise machined several times, to meet an appearance standard. Manufacturing costs will thus be saved.

While the present disclosure has been described with reference to particular embodiments, the description is illustrative of the disclosure and is not to be construed as limiting the disclosure. Therefore, various modifications can be made to the embodiments by those of ordinary skill in the art without departing from the true spirit and scope of the disclosure, as defined by the appended claims.

What is claimed is:

1. A housing assembly, comprising:
a housing defining a jack socket hole; and
a bumper insert being made of plastic material, the bumper insert inserted in the jack socket hole, and the bumper insert defining a connecting hole.

2. The housing assembly of claim 1, wherein the bumper insert comprises a mounting portion and an insertion portion, the insertion portion protrudes from the mounting portion and passes through the jack socket hole, and the connecting hole is defined through the mounting portion and the insertion portion.

3. The housing assembly of claim 2, wherein the housing comprises a bottom wall and a peripheral wall extending from edges of the bottom wall by bending in a curved shape, the peripheral wall comprises an inner surface and an outer surface opposite to the inner surface thereof, the connecting hole is defined through the peripheral wall, and the mounting portion is mounted on the inner surface of the peripheral wall.

4. The housing assembly of claim 3, wherein an end surface of the insertion portion away from the inner surface of the peripheral wall is coplanar with edges of the jack socket hole.

5. The housing assembly of claim 2, wherein an outer wall of the insertion portion conforms in size and shape to an inner wall of the jack socket hole.

6. An electronic device comprising:
a housing assembly, comprising:
a housing defining a jack socket hole; and
a bumper insert being made of plastic material, the bumper insert inserted in the jack hole, and the bumper insert defining a connecting hole; and
a functional module positioned in the housing.

7. The housing assembly of claim 6, wherein the bumper insert comprises a mounting portion received in the housing and an insertion portion, the insertion portion protrudes from the mounting portion and passes through the jack socket hole, and the connecting hole is defined through the mounting portion and the insertion portion.

8. The housing assembly of claim 7, wherein the housing comprises a bottom wall and a peripheral wall extending from edges of the bottom wall by bending with a curvature, the peripheral wall comprises an inner surface and an outer surface opposite to the inner surface, the connecting hole is defined through the peripheral wall, and the mounting portion is mounted on the inner surface of the peripheral wall.

9. The housing assembly of claim 8, wherein an end surface of the insertion portion away from the inner surface is coplanar with edges of the jack socket hole.

10. The housing assembly of claim 7, wherein an outer wall of the insertion portion conforms in size and shape to an inner wall of the jack socket hole.
